(19) United States
(12) Patent Application Publication
(10) Pub. No.: US 2024/0128365 A1
(43) Pub. Date: Apr. 18, 2024

(54) NITRIDE BASED SEMICONDUCTOR DEVICE AND METHOD FOR MANUFACTURING SAME

(71) Applicant: DB HiTek Co., Ltd., Bucheon-si (KR)

(72) Inventors: Min Su CHO, Eumseong-gun (KR); Jin Hyo JUNG, Eumseong-gun (KR)

(21) Appl. No.: 18/303,638

(22) Filed: Apr. 20, 2023

(30) Foreign Application Priority Data
Oct. 12, 2022 (KR) 10-2022-0130158

(51) Int. Cl. H01L 29/778; H01L 29/20; H01L 29/40; H01L 29/423; H01L 29/66

(52) U.S. Cl. CPC H01L 29/7786; H01L 29/2003; H01L 29/401; H01L 29/42316; H01L 29/66462

(57) ABSTRACT

Disclosed are a nitride-based semiconductor device and a method of manufacturing the same. The device has improved frequency characteristics because it has a shorter gate length than existing devices. The shorter gate length can be obtained without using a high-performance patterning device or technology using the patterning device.

The present application claims priority to Korean Patent Application No. 10-2022-0130158, filed Oct. 12, 2022, the entire contents of which are incorporated herein for all purposes by this reference.

### BACKGROUND OF THE INVENTION

### 1. Field of the Invention

The present disclosure relates to a nitride-based semiconductor device and a method for manufacturing the same. More particularly, the present disclosure relates to a nitride-based semiconductor device having improved frequency characteristics due to a decreased gate electrode length compared to existing devices. The decreased gate length is achieved without using a high-performance patterning device or technology using the patterning device.

### 2. Description of the Related Art

Nitride-based semiconductor devices have high saturation electron velocity and wide band gap characteristics and are widely applied in power semiconductor fields or RF fields. In particular, AlGaN/GaN high-electron-mobility transistors (HEMTs) using a high carrier concentration and electron mobility of a 2-dimensional electron gas (2-DEG) at or near an AlGaN/GaN heterojunction are utilized. In power semiconductor devices, E-mode HEMT manufacturing technology with normally-off characteristics using P-GaN thin films has been commercialized, and the technology is continuously being developed.

On the other hand, in RF devices, it is necessary to manufacture a D-mode HEMT to obtain high-frequency characteristics. It is desirable to have a short gate length for operating characteristics in the mm-wave and sub-6 GHz frequency bands.

FIG. 1 is a cross-sectional view of a conventional nitride-based semiconductor device 9.

Hereinafter, the structure and problems of the conventional nitride-based semiconductor device 9 will be briefly described.

Referring to FIG. 1, in the conventional nitride semiconductor device 9, a channel layer 910 is on a substrate 901, a bather layer 920 is on the channel layer 910, and a source electrode 930, a drain electrode 940, and a gate electrode 950 are on the bather layer 920. In addition, a passivation layer 960 may at least partially cover the sidewalls of the source electrode 930, the drain electrode 940, and the gate electrode 950.

In the process of manufacturing the semiconductor device 9, the gate length L of the gate electrode 950 is determined in the process of forming the passivation layer 960 and will be described in detail below.

FIGS. 2 and 3 are cross-sectional views illustrating a conventional nitride-based semiconductor device manufacturing process according to FIG. 1.

Referring to FIG. 2, a process of forming the gate electrode 950 is shown in detail. A patterned photoresist film (not shown) is formed on the passivation layer 960. The source electrode 930 and the drain electrode 940 (not shown) are formed in the passivation layer 960 prior to forming the patterned photoresist film. The photoresist layer is patterned with an opening exposing the passivation layer 960 where the gate electrode 950 is to be formed.

Then, an opening 961 is formed by etching the passivation layer 960 using the patterned photoresist layer as a mask. Thereafter, referring to FIG. 3, a metal film 951 is deposited in the opening 961 and on the passivation layer 960, and the gate electrode 950 is formed by removing parts of the metal layer 951.

Accordingly, the gate length L of the gate electrode 950 is determined by the width of the opening 961, and relatively high-performance patterning equipment and technology are used to form the gate electrode 950 with a short length L. Therefore, the disadvantages of high cost and relative difficulty in manufacturing may occur.

In order to solve this problem, the present inventors have conceived a nitride-based semiconductor device 1 having an improved structure and a method for manufacturing the same, which will be described in detail later.

### RELATED ART

Korean Patent Application Publication No. 10-2020-0068745, entitled “High Electron Mobility Transistor.”

### SUMMARY OF THE INVENTION

The present disclosure was devised to solve the problems of the related art, and an objective of the present disclosure is to provide a nitride-based semiconductor device and a method for manufacturing the same, which can improve the frequency characteristics of an RF device by allowing the length of a gate electrode to be controlled or reduced using a sidewall spacer containing an insulating material, without using separate, relatively high-performance patterning (e.g., photolithography) equipment.

In addition, another objective of the present disclosure is to provide a nitride-based semiconductor device and a method of manufacturing the same, which reduces or prevents unnecessary damage caused by repeated exposure of the bather layer or cap layer during manufacturing by forming or including a protrusion on the insulating film, which may inhibit or prevent the sidewall spacer (e.g., a bottommost surface thereof) from directly contacting the bather layer or cap layer.

In addition, still another objective of the present disclosure is to provide a nitride-based semiconductor device and a method of manufacturing the same, which reduces or prevents leakage current generated by the gate electrode by forming or including a metal-insulator-semiconductor (MIS) gate electrode structure.

In addition, still another objective of the present disclosure is to provide a nitride-based semiconductor device and a manufacturing method thereof capable of improving the breakdown voltage and reducing the surface leakage current of the device by forming or including an optional cap layer on the bather layer.

In order to achieve the above-mentioned objectives, the present disclosure proposes various embodiments described below.

According to one or more embodiments of the present disclosure, a nitride-based semiconductor device according to the present disclosure includes a substrate; a channel layer on the substrate; a bather layer on the channel layer; a source electrode on the bather layer and spaced apart from the gate electrode; a drain electrode on the bather layer and spaced apart from the gate electrode; a gate electrode on the bather layer; an insulating film on the bather layer and having openings at positions corresponding to the source electrode, the drain electrode, and the gate electrode; and a sidewall spacer between the gate electrode and a nearest sidewall of the insulating film.

According to one or more other or further embodiments of the present disclosure, the sidewall spacer of the nitride-based semiconductor device according to the present disclosure includes an insulating material.

According to one or more other or further embodiments of the present disclosure, the sidewall spacer in the nitride-based semiconductor device according to the present disclosure includes the same material as the insulating film.

According to one or more other or further embodiments of the present disclosure, the sidewall spacer in the nitride-based semiconductor device according to the present disclosure is formed after forming the insulating film.

According to one or more other or further embodiments of the present disclosure, the nitride-based semiconductor device according to the present disclosure further includes a cap layer comprising an undoped region between the bather layer and the insulating film.

According to one or more other or further embodiments of the present disclosure, a nitride-based semiconductor device according to the present disclosure includes a substrate; a channel layer on the substrate; a bather layer on the channel layer; a gate electrode on the bather layer; an insulating film on the bather layer and having an opening at a position corresponding to the gate electrode; and a sidewall spacer between the gate electrode and a nearest sidewall of the insulating film, in which the insulating film comprises a protrusion into the opening.

According to one or more other or further embodiments of the present disclosure, the sidewall spacer in the nitride-based semiconductor device according to the present disclosure is on the protrusion and on the nearest sidewall of the insulating film.

According to one or more other or further embodiments of the present disclosure, the protrusion in the nitride-based semiconductor device according to the present disclosure is at or below a lowest end or surface of the nearest sidewall of the insulating film and has a height smaller than that of the nearest sidewall of the insulating film.

According to one or more other or further embodiments of the present disclosure, the sidewall spacer in the nitride-based semiconductor device according to the present disclosure includes an insulating material and comprises a plurality of layers (e.g., it has a multilayer structure).

According to one or more other or further embodiments of the present disclosure, the nitride-based semiconductor device according to the present disclosure further includes a cap layer comprising an undoped region between the bather layer and the insulating film.

According to one or more other or further embodiments of the present disclosure, a nitride-based semiconductor device according to the present disclosure includes a substrate; a channel layer on the substrate; a bather layer on the channel layer; a gate electrode on the bather layer; a first insulating film on the bather layer and having an opening at a position corresponding to the gate electrode; a second insulating film on the first insulating film; and the gate electrode on the second insulating film.

According to one or more other or further embodiments of the present disclosure, the second insulating film in the nitride-based semiconductor device according to the present disclosure, is on (e.g., extends continuously without interruption) the first insulating film and along the nearest sidewall of the insulating film in the opening.

According to one or more other or further embodiments of the present disclosure, the gate electrode in the nitride-based semiconductor device according to the present disclosure is not in direct contact with the first insulating film.

According to one or more other or further embodiments of the present disclosure, the nitride-based semiconductor device according to the present disclosure further includes a buffer layer between the substrate and the channel layer.

According to one or more other or further embodiments of the present disclosure, the second insulating film in the nitride-based semiconductor device according to the present disclosure includes a bottom surface in contact with the gate electrode; and a sidewall spacer in contact with the second insulating film and on the gate electrode and the nearest sidewall of the insulating film.

According to one or more embodiments of the present disclosure, a method for manufacturing a nitride-based semiconductor device according to the present disclosure includes forming a channel layer on a substrate, the channel layer comprising a GaN semiconductor; forming a bather layer on the channel layer, the bather layer comprising a AlGaN semiconductor; forming a source electrode and a drain electrode on the bather layer; forming an insulating film having an opening on the bather layer, the insulating film having a sidewall in the opening; forming a sidewall spacer on the sidewall of the insulating film; and forming a gate electrode on the sidewall spacer.

According to one or more other or further embodiments of the present disclosure, the sidewall spacer in the method for manufacturing a nitride-based semiconductor device according to the present disclosure includes an insulating material.

According to one or more other or further embodiments of the present disclosure, the sidewall spacer-forming step in the method for manufacturing a nitride-based semiconductor device according to the present disclosure may include forming a patterned photoresist film on the insulating layer, the patterned photoresist film exposing the insulating layer at a position for a gate electrode; forming the opening in the insulating film by etching the insulating layer, using the patterned photoresist film as a mask; forming a second insulating film on the insulating film and in the opening; and etching the second insulating film.

According to one or more other or further embodiments of the present disclosure, the gate electrode-forming step in the method of manufacturing a nitride-based semiconductor device according to the present disclosure includes forming a metal layer on the insulating film and the sidewall spacer; and forming the gate electrode by etching the metal layer.

With the configurations described above, the present disclosure has various advantages described below.

The present disclosure has the effect of improving the frequency characteristics of an RF device including the present nitride-based semiconductor device by decreasing the length of a gate electrode using a sidewall spacer including an insulating material, without using separate, relatively high-performance patterning equipment.

In addition, the present disclosure has the effect of reducing or preventing unnecessary damage caused by multiple exposures of the bather layer or cap layer during the manufacturing process by forming or including one or more protrusions on the insulating film so that the sidewall spacer does not directly contact the bather layer or cap layer.

In addition, in the present disclosure, the gate electrode may comprise a metal-insulator-semiconductor (MIS) structure, thereby reducing or preventing leakage current generated by the corresponding gate electrode.

In addition, the present disclosure shows the effect of enabling a breakdown voltage improvement and surface leakage current reduction of the device by forming or including an optional cap layer on the bather layer.

On the other hand, even if certain effects are not explicitly mentioned here, the effects described in the following specification that are expected or realized from the technical features of the present disclosure and their provisional effects are treated as if described in the present specification.

### BRIEF DESCRIPTION OF THE DRAWINGS

FIG. 1 is a cross-sectional view of a conventional nitride-based semiconductor device;

FIGS. 2 and 3 are cross-sectional views illustrating a conventional process for manufacturing a nitride-based semiconductor device according to FIG. 1;

FIG. 4 is a cross-sectional view of a nitride-based semiconductor device according to a first embodiment of the present disclosure;

FIG. 5 is a cross-sectional view of a nitride-based semiconductor device according to a second embodiment of the present disclosure;

FIG. 6 is a cross-sectional view illustrating a structure in a process of manufacturing a nitride-based semiconductor device according to FIG. 5;

FIG. 7 is a cross-sectional view of a nitride-based semiconductor device according to a third embodiment of the present disclosure; and

FIGS. 8 to 15 are cross-sectional views illustrating a method for manufacturing a nitride-based semiconductor device according to one or more embodiments of the present disclosure.

### DESCRIPTION OF THE EMBODIMENTS

Hereinafter, embodiments of the present disclosure will be described in more detail with reference to the accompanying drawings. Embodiments of the present disclosure may be modified in various forms, and the scope of the present disclosure should not be construed as being limited to the following examples, but should be interpreted based on the matters described in the claims. In addition, the embodiments are provided as a reference for more completely explaining the present disclosure to those skilled in the art.

As used in the present specification, the singular form may include the plural form, unless clearly indicated otherwise in the context of use. Furthermore, when used herein, the terms “comprise” and/or “comprising” specify the presence or addition of one or more other shapes, numbers, steps, operations, members, elements, and/or groups to those mentioned, and do not exclude the presence or addition of one or more other shapes, numbers, operations, elements, and/or groups.

Hereinafter, when one component (or layer) is described as being on another component (or layer), it should be noted that one component may be directly on another component, or another component(s) or layer(s) may be between the one component and the other component. In addition, when an element is expressed as being directly on or above another element, no other element is between the corresponding elements. Also, a component being on the “upper”, “upper”, “lower”, “upper”, “lower” or “one side” or “side” of another component means a relative positional relationship between the components.

Meanwhile, when an embodiment can be implemented differently, specific functions or operations may occur in a different order from the order described. For example, two consecutive functions or operations described herein may be performed substantially simultaneously or in reverse sequence.

Hereinafter, a first conductivity type impurity region may be, for example, a “P-type” region, and a second conductivity type impurity region may be an “N-type” region. Alternatively, in some cases, the first conductivity type impurity region may be an “N-type” region, and the second conductivity type impurity region may be a “P-type” doped region, but is not limited thereto.

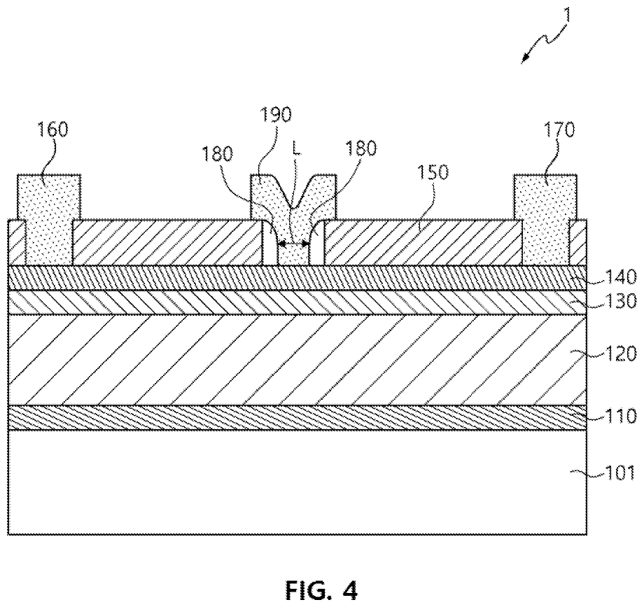

FIG. 4 is a cross-sectional view of a nitride-based semiconductor device according to a first embodiment of the present disclosure.

Hereinafter, the nitride-based semiconductor device 1 according to the first embodiment of the present disclosure will be described in detail with reference to the accompanying drawings.

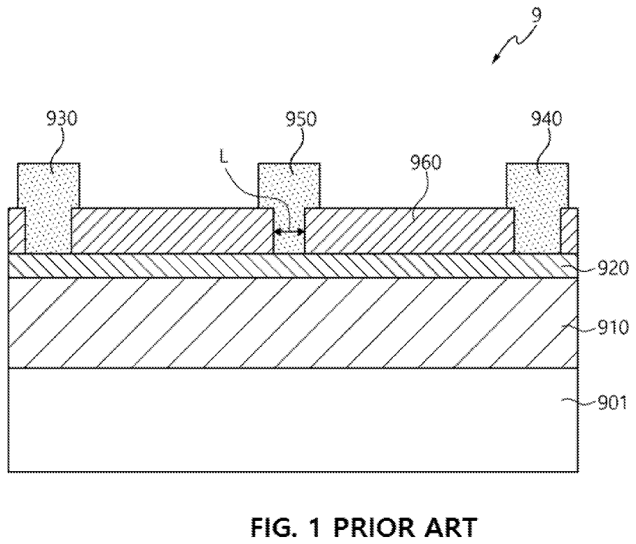

Referring to FIG. 4, the present disclosure relates to a nitride-based semiconductor device 1, and more particularly, the present disclosure relates to a nitride-based semiconductor device 1 that improves frequency characteristics of a device by decreasing a gate electrode length relative to an otherwise identical conventional device 9 according to FIG. 1 without using a relatively high-performance patterning device (e.g., photolithography stepper and/or scanner).

To this end, the nitride-based semiconductor device 1 may include a substrate 101, a buffer layer 110, a channel layer 120, a bather layer 130, a cap layer 140, an insulating film 150, a source electrode 160, a drain electrode 170, a sidewall spacer 180, and a gate electrode 190.

The substrate 101 comprises, for example, a silicon substrate (e.g., a monolithic or single-crystal silicon wafer), but is not limited thereto. As another example, the substrate 101 may be a sapphire substrate, a GaN substrate, or a SiC substrate. In the present disclosure, an example of the substrate 101 is a silicon substrate.

The buffer layer 110 is on the substrate 101 and may be formed, for example, by epitaxial growth of AlN on the substrate 101 to a predetermined thickness. Alternatively, the buffer layer 110 may comprise one or more composite layers of GaN and AlGaN, but is not limited thereto. The buffer layer 110 may reduce or prevent stress caused by differences in the lattice constants and coefficients of thermal expansion between the substrate 101 and the channel layer 120 to be described later.

The buffer layer 110 may be doped with one or more impurities such as C and/or Fe. However, it should be noted that the buffer layer 110 may be omitted from the structure of the present disclosure and is not an essential component of the present disclosure. In this case, the channel layer 120 to be described later may be directly on the substrate 101, for example, and is not limited thereto.

The channel layer 120 is on the substrate 101 or the buffer layer 110, and may comprise, for example, a nitride-based semiconductor such as GaN.

The bather layer 130 is on the channel layer 120 and may comprise, for example, a nitride-based semiconductor such as AlGaN. The channel layer 120 and the bather layer 130 preferably comprise different nitride-based semiconductors. With this structure, a 2-dimensional electron gas (2DEG) layer (not shown) may form near the interface between the channel layer 120 and the bather layer 130 during use of the device 1.

The density and mobility of the 2DEG layer may be controlled by adjusting the content of Al and Ga in the bather layer 130. The 2DEG layer may form in the channel layer 120. Accordingly, a channel region having a predetermined thickness may form in the channel layer 120, near the interface with the bather layer 130. That is, it should be noted that the channel region may not form in or throughout the entire channel layer 120.

The cap layer 140 is on the bather layer 130 and may comprise an epitaxial layer. The cap layer 140 may improve the breakdown voltage of the device 1 and/or reduce surface leakage current in the device 1. In addition, the cap layer 105 may comprise GaN, and is not an essential component of the present disclosure. The cap layer 105 may be undoped, but is not limited thereto.

The insulating film 150 comprises a material having electrical insulating properties. The insulating film 150 is on the bather layer 130 or the cap layer 140, and may include, for example, a single-layer film or a multi-layer film. Each film in the insulating film 150 may comprise an insulating oxide or nitride such as SiN, Al₂O₃, and/or SiO₂. However, the scope of the present disclosure is not limited by specific examples.

The source electrode 160, the drain electrode 170, and the gate electrode 190 to be described later are at least in part in the insulating film 150. Preferably, at least one part of the source electrode 160, the drain electrode 170, and the gate electrode 190 passes through the insulating film 150, and a detailed description thereof will be described later. Accordingly, the insulating film 150 may be on the bather layer 130 or the cap layer 140, and the insulating layer 150 may have openings therein for the source electrode 160, the drain electrode 170, and the gate electrode 190 or parts thereof.

The source electrode 160 and the drain electrode 170 are separate from the gate electrode 190 to be described later, and are on the bather layer 130 or the cap layer 140. For example, it should be noted that the source electrode 160 and the drain electrode 170 may have a stepped cross-sectional shape or a rectangular cross-sectional shape, but may also have various other structures. In addition, the source electrode 150, the gate electrode 190, and the drain electrode 170 may be spaced apart from each other in a horizontal direction, as shown in FIG. 4. The source electrode 160 and the drain electrode 180 may comprise, for example, a single layer or a composite layer of various conductive metals capable of ohmic contact, such as Ti, Au, and Al, and there is no separate limitation thereto.

The sidewall spacer 180 is between the insulating film 150 and the gate electrode 190, and may comprise a material having electrical insulating properties like the aforementioned insulating film 150. In addition, the sidewall spacer 180 may comprise a nitride such as SiN or an oxide such as Al₂O₃ and/or SiO₂, and may comprise the same material as the insulating film 150 or include the same material, but the scope of this disclosure is not limited thereto. In addition, the sidewall spacer 180 may a multi-layered oxide and/or nitride film.

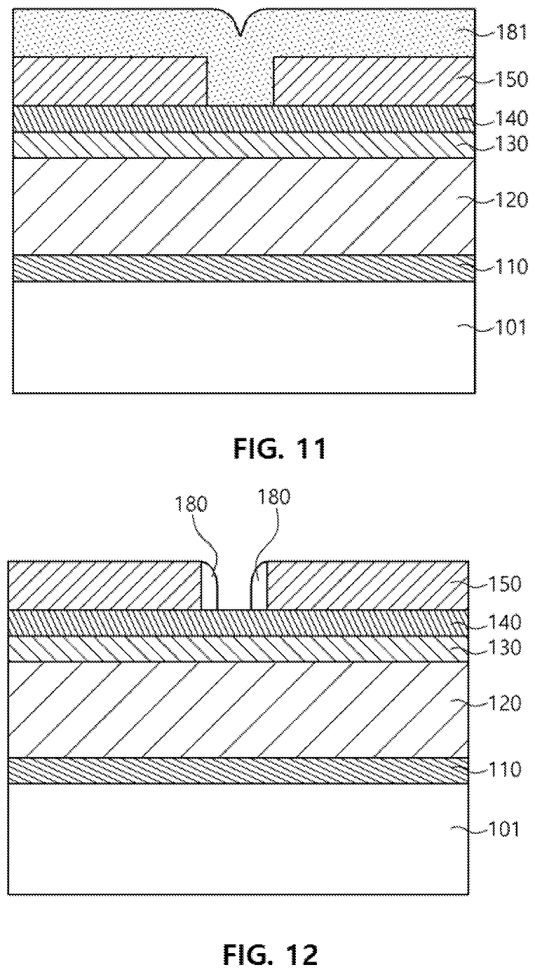

Although described in detail below, the sidewall spacer 180 can be naturally formed by depositing an insulating layer 181 (see FIG. 11) on the insulating film 180, and then etching the insulating layer 181 without using a separate mask pattern. In this case, the etching process may comprise anisotropic etching, but the scope of the present disclosure is not limited thereto.

A space for the gate electrode 190 in the opening in the insulating film 150 may be defined by the sidewall spacer 180. There is an advantage in being able to control or reduce the gate length L without using separate, relatively high-performance patterning equipment, and a detailed description thereof will be described later.

The gate electrode 190 is on the bather layer 130 or the cap layer 140 and may comprise, for example, a single layer or a composite layer of various conductive metals such as Ti and/or Pd.

Hereinafter, the advantages of the nitride-based semiconductor device 1 according to embodiments of the present disclosure, together with the structure and problems of the conventional nitride-based semiconductor device 9, will be described in detail.

Referring to FIG. 1, in the conventional nitride semiconductor device 9, a channel layer 910 is formed on a substrate 901, a bather layer 920 is formed on the channel layer 910, and a source electrode 930, a drain electrode 940, and a gate electrode 950 are on the bather layer 920. In addition, the passivation layer 960 may at least partially cover the sidewalls of the source electrode 930, the drain electrode 940, and the gate electrode 950.

In the process of manufacturing the semiconductor device 9, the gate length L of the gate electrode 950 is determined in the process of forming the passivation layer 960.

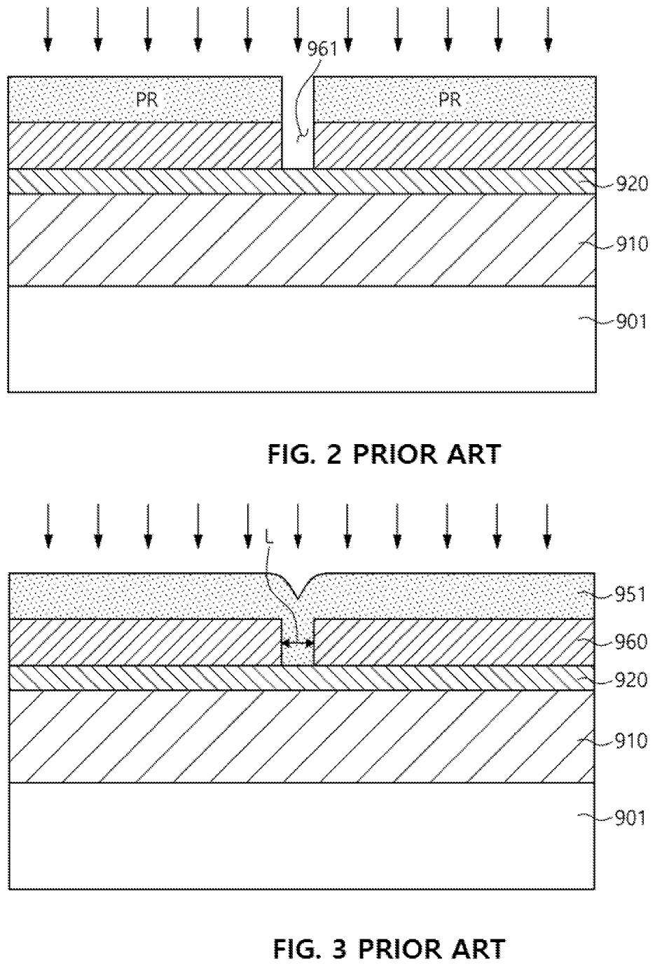

Referring to FIG. 2, a process of forming the gate electrode 950 is shown in detail. A patterned photoresist film (not shown) is formed on the passivation layer 960. The source electrode 930 and the drain electrode 940 (not shown) are formed in the passivation layer 960 prior to forming the patterned photoresist film. The photoresist layer is patterned with an opening exposing the passivation layer 960 where the gate electrode 950 is to be formed.

Then, an opening 961 is formed by etching the passivation layer 960 using the patterned photoresist layer. Thereafter, referring to FIG. 3, a metal film 951 is deposited in the opening 961 and on the passivation layer 960, and the gate electrode 950 is formed by removing parts of the metal layer 951.

Accordingly, the gate length L of the gate electrode 950 is determined by the width of the opening 961, and relatively high-performance patterning equipment and technology are used to form the gate electrode 950 length L with a short length L. Therefore, the disadvantage of high cost and relative difficulty in manufacturing may occur.

In general, a cut-off frequency (fT), which is an indicator of performance of an RF device, may be defined as in Formula (1):

fT=gM/(2π*(Cgs+Cgd+Cp)) (1)

In Formula (1), gM is the transconductance (e.g., of the RF device), Cgs and Cgd are the internal capacitances between (i) the gate and the source and (ii) the gate and the drain, respectively, and Cp is the parasitic gate-bulk capacitance (e.g., of the RF device) outside the channel. In addition, gM has an inversely proportional relationship with the length of the gate electrode 950. Therefore, it can be seen that the shorter the gate length, the better the RF performance.

Referring to FIG. 4, in order to solve the above-described problem(s) of the device 9, the nitride-based semiconductor device 1 according to one or more embodiments of the present disclosure includes a sidewall spacer 180 between the insulating film 150 and the gate electrode 190. The sidewall spacer 180 is in an opening in the insulating film 150 where the gate electrode 190 is to be formed. This opening exposes the bather layer 130 and the cap layer 140 before the gate electrode 190 is formed. Accordingly, the sidewall spacer 180 may define the gate length L of the gate electrode 190, and in detail, the gate length L may be shorter than an otherwise identical device 1 in accordance with FIGS. 1-3, without using a separate and/or relatively high-performance patterning device.

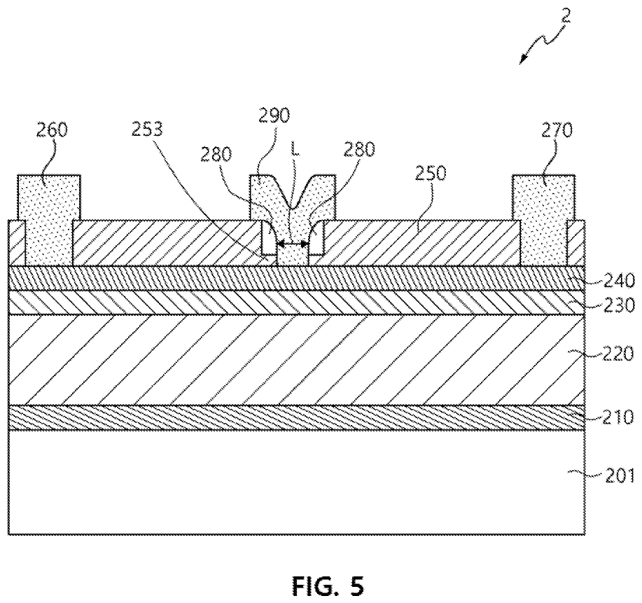

FIG. 5 is a cross-sectional view of a nitride-based semiconductor device according to a second embodiment of the present disclosure.

Hereinafter, the nitride-based semiconductor device 2 according to the second embodiment of the present disclosure will be described in detail with reference to the accompanying drawings.

Since substrate 201, a buffer layer 210, a channel layer 220, a bather layer 230, a cap layer 240, a source electrode 260, a drain electrode 270, a gate electrode 290 in the second embodiment is substantially the same as the corresponding components of the first embodiment, a detailed description thereof will be omitted.

Referring to FIG. 5, in the second embodiment, a protrusion 253 protruding or extending from the insulating film 250 (e.g., a sidewall thereof) may be below the sidewall spacer 280. In a cross-sectional view, the protrusion 253 may extend from across the opening in the insulating layer 250 in which the gate electrode 290 is formed.

In addition, in the second embodiment, the insulating film 250 and the sidewall spacer 280 are formed in different processes, and the bottom of the sidewall spacer 280 does not directly contact the bather layer 230 or the cap layer 240 due to the protrusion 253. The protrusion 253 of the insulating film 250 may be between the sidewall spacer 280 and the bather layer 230 or the cap layer 240. In addition, it is preferable that the protrusion 253 has a further opening therein exposing the bather layer 230 or the cap layer 240 (e.g., prior to formation of the gate electrode 290). The protrusion 253 may have a width (e.g., along the direction of extension from the sidewall of the insulating film 250) equal to a thickness of the sidewall spacer 280.

The advantages of the nitride-based semiconductor device 2, according to the second embodiment, are as follows.

In the process of manufacturing the nitride-based semiconductor device 1 according to the first embodiment, etching the first insulating film 151 to form the insulating layer 150 exposes the bather layer 130 or the cap layer 140 on which the gate electrode 190 is to be formed (see FIG. 10). Damage may occur to the exposed surface of the bather layer 130 or the cap layer 140. In addition, in the process of etching after depositing the second insulating layer 181 on the insulating film 150 to form the sidewall spacer 180, the bather layer 130 or the cap layer 140 in the same area is exposed again, and additional damage may occur (see FIGS. 11 and 12).

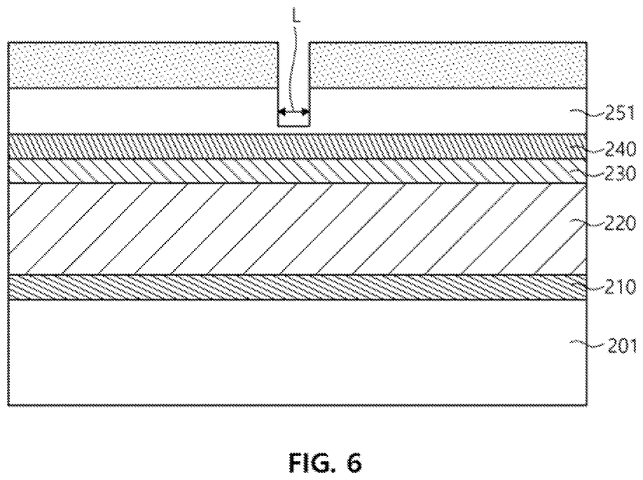

FIGS. 5 and 6 are cross-sectional views illustrating structures formed during the process of manufacturing a nitride-based semiconductor device according to FIG. 5.

Referring to FIG. 6, in the nitride-based semiconductor device 2 according to the second embodiment, the first insulating layer 251 is etched to a depth less than the thickness of the first insulating layer 251. As a result, the surface of the bather layer 230 or the cap layer 240 is not exposed. Therefore, the first insulating layer 251 is not etched entirely through, it is possible to prevent at least one occurrence of damage. The remaining portion of the insulating film 251 where the gate electrode 290 is to be formed, other than the protrusion 253, is etched when etching an insulating film (not shown) for forming the sidewall spacer 280 later. The bather layer 230 and the cap layer 240 may be exposed at that time (see FIGS. 11 and 12).

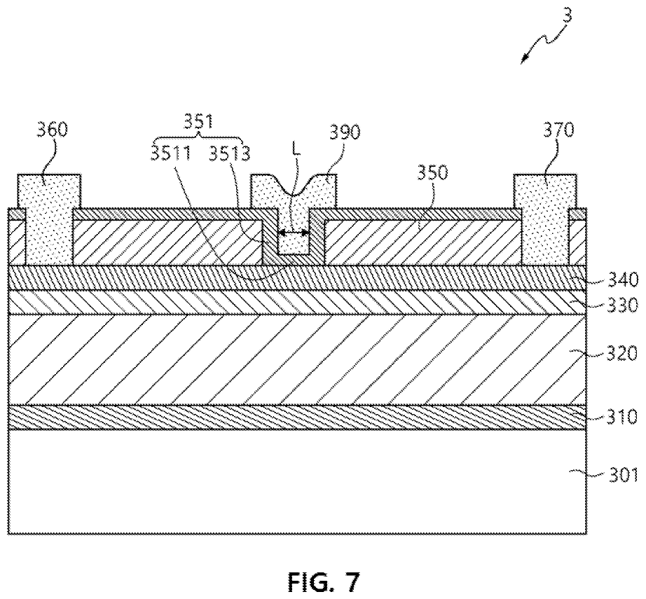

FIG. 7 is a cross-sectional view of a nitride-based semiconductor device according to a third embodiment of the present disclosure.

Hereinafter, the nitride-based semiconductor device 3 according to the third embodiment of the present disclosure will be described in detail with reference to the accompanying drawings.

In the third embodiment, since the substrate 301, the buffer layer 310, the channel layer 320, the bather layer 330, the cap layer 340, the insulating film 350, the source electrode 360, the drain electrode 370, and the gate electrode 390 are substantially the same as the corresponding components of the first and second embodiments, detailed descriptions thereof will be omitted.

Referring to FIG. 7, in the third embodiment, an additional insulating film 351 may be on the insulating film 350. In this case, the insulating film 350 is referred to as a “first insulating film 350”, and the insulating film 351 is referred to as a “second insulating film 351”. The second insulating film 351 may include or comprise the same material as the first insulating film 350, but it generally comprises a material having electrical insulating properties.

In addition, the second insulating film 351 is along the sidewall of the first insulating film 350 (e.g., in the opening in which the gate electrode 390 is to be formed) and on the bather layer 330 or the cap layer 340 in the opening. Therefore, no part of the gate electrode 390 directly contacts the first insulating film 350, and instead, the gate electrode 390 contacts the second insulating film 351. That is, the second insulating film 351 may include a bottom part 3511 between the gate electrode 390 and the bather layer 330 or the cap layer 340. The second insulating film 351 may also include a sidewall spacer part 3513 between the gate electrode 390 and the first insulating film 350.

By forming a metal-insulator-semiconductor (MIS) structure with the second insulating layer 351, as described above, leakage current generated in or by the gate electrode 390 (e.g., through the bather layer 330 or the cap layer 340) can be reduced or prevented. In addition, since it is not necessary to etch the second insulating film 351 in the opening for the gate electrode 390, the third embodiment may offer additional convenience and cost reduction advantages.

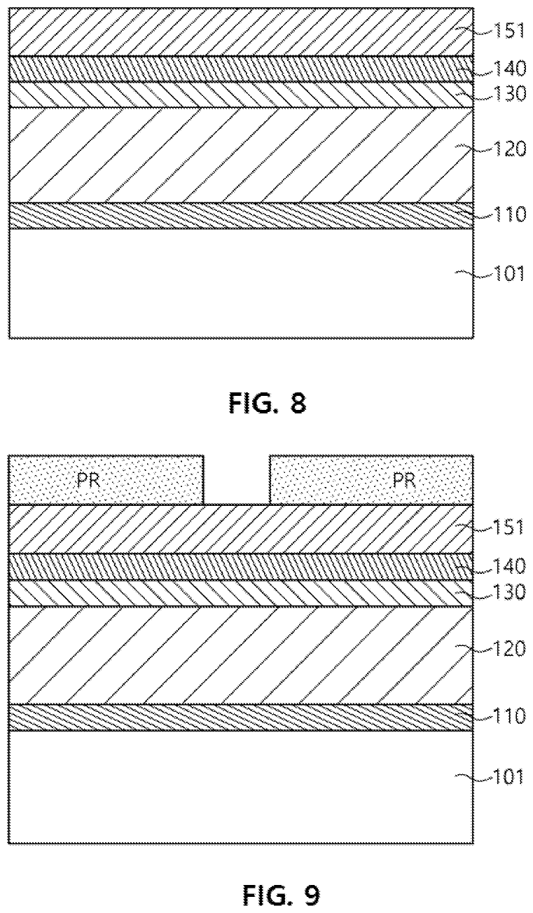

FIGS. 8 to 15 are cross-sectional views illustrating structures formed during a method for manufacturing a nitride-based semiconductor device according to one or more embodiments of the present disclosure. For the convenience of description, it should be noted that the illustration of the source electrode and the drain electrode and their formation are omitted.

Hereinafter, a method for manufacturing a nitride-based semiconductor device according to one or more embodiments of the present disclosure will be described in detail with reference to the accompanying drawings. Also, for convenience, the following description will be made based on the method of manufacturing the semiconductor device 1 according to the first embodiment.

Referring to FIG. 8, a buffer layer 110, a channel layer 120, and a bather layer 130 are sequentially formed on a substrate 101, for example by epitaxial growth. As described above, the substrate 101 may be any one of a single-crystal silicon substrate, a crystalline sapphire substrate, a GaN substrate, and a SiC substrate adapted or configured for subsequent epitaxial growth of GaN and/or AlGaN semiconductor material thereon, but in the present disclosure, a single-crystal silicon substrate will be described as an example. It should be noted that the buffer layer 110 may be formed on the substrate 101 by epitaxially growing an AlN layer to a predetermined thickness, but forming the buffer layer 110 is not an essential component of the present disclosure.

In addition, the channel layer 120 on the buffer layer 110 is a nitride-based semiconductor layer such as GaN, the bather layer 130 is a nitride-based semiconductor layer such as AlGaN, and a 2DEG layer (not shown) may formed at the interface of the channel layer 120 and the bather layer 130 (e.g., from carriers such as electrons accumulating at the interface). In detail, piezoelectric polarization may occur at the interface between the channel layer 120 and the bather layer 130 due to a difference in lattice constants between GaN and AlGaN. The piezoelectric polarization and/or a spontaneous polarization of the channel layer 120 and the bather layer 130 may result in a two-dimensional electron gas having a high electron concentration at the interface between the channel layer 120 and the bather layer 130.

In addition, the cap layer 140 may comprise GaN and be formed on the bather layer 130 by epitaxially growth, but it should be noted that it is not an essential component of the present disclosure.

Then, a first insulating layer 151 is formed on the bather layer 130 or the cap layer 140. The first insulating layer 151 may comprise a nitride film such as SiN or an oxide film such as Al₂O₃ and/or SiO₂, but the scope of the present disclosure is not limited by a specific example. The first insulating layer 151 is etched (e.g., following photolithographic patterning of a photoresist to define openings in the first insulating layer 151 corresponding to the source electrode 160 and the drain electrode 170) in a subsequent process to form the insulating film 150. For the convenience of description, the first insulating layer 151 and the insulating film 150 are not distinguished below.

Then, the source electrode 160 and the drain electrode 170 are formed (not shown). The source electrode 160 and the drain electrode 170 may be formed using known processing (e.g., blanket deposition of one or more metal, metal alloy and/or conductive metal nitride layers, photolithographic patterning of a photoresist thereon, and etching to remove parts of metal, metal alloy and/or conductive metal nitride layers other than those forming the source electrode 160 and the drain electrode 170), and a detailed description thereof will be omitted.

Later, the sidewall spacer 180 is formed in the first insulating layer 151, and a process for doing so will be described in detail.

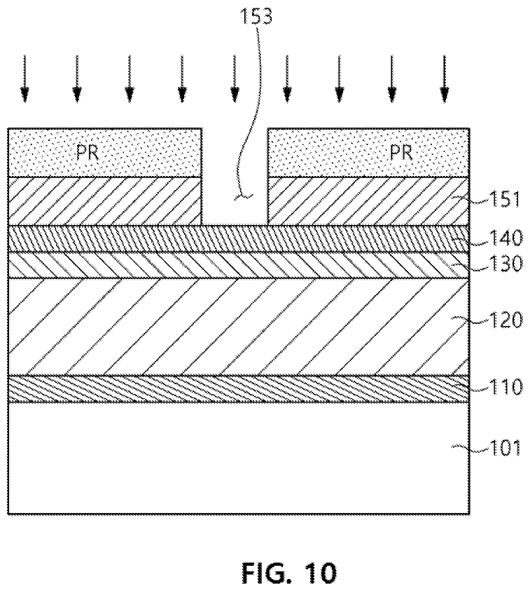

Referring to FIG. 9, first, a patterned photoresist layer PR is formed on the first insulating layer 151 with an opening corresponding to the gate electrode 190. After that, referring to FIG. 10, the exposed first insulating layer 151 is etched using the patterned photoresist film PR as a mask. Accordingly, an opening 153 exposing the bather layer 130 or the cap layer 140 may be formed. In this way, the insulating film 150 is completed.

Then, referring to FIG. 11, a second insulating layer 181 comprising the same material as the sidewall spacer 180 is formed on the insulating layer 150, along the sidewalls of the insulating film 150 in the opening 153, and on the exposed bather layer 130 or cap layer 140. Then, referring to FIG. 12, the second insulating layer 181 is anisotropically etched to form the sidewall spacer 180, and as described above, a separate mask pattern is not required.

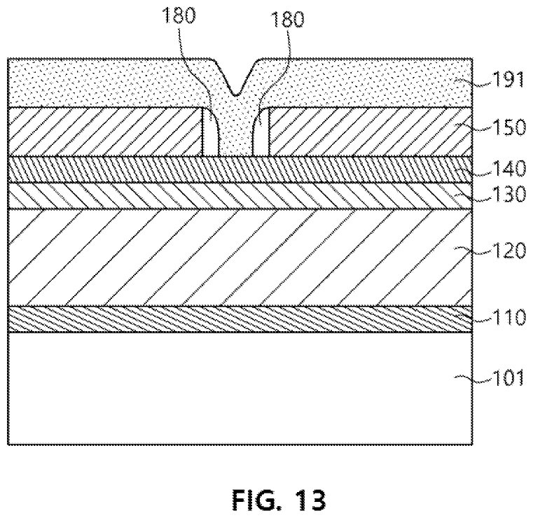

As a subsequent process, referring to FIG. 13, a metal layer 191 is formed (e.g., by blanket deposition, such as sputtering, chemical vapor deposition [CVD], atomic layer deposition [ALD], etc.) on the insulating film 150 and the sidewall spacer 180 to fill the remaining space in the opening 153. The metal layer 191 may comprise the same material as the gate electrode 190.

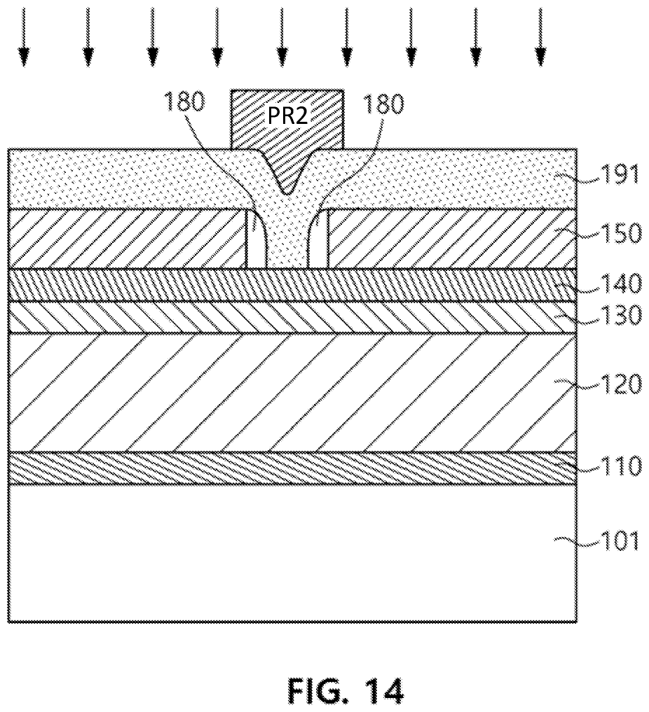

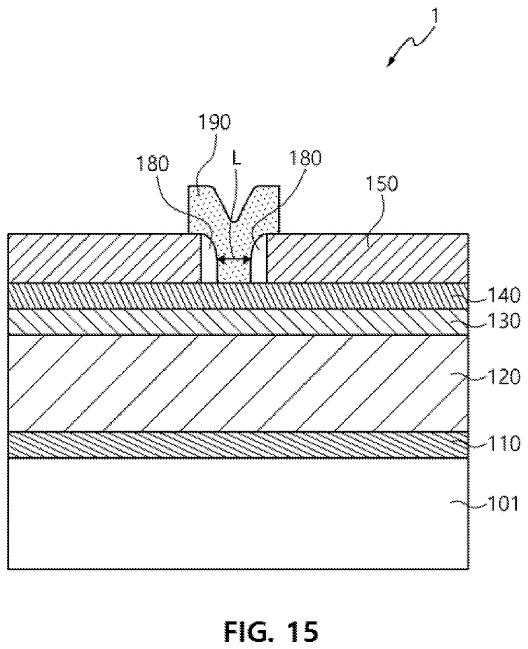

Then, the metal layer 191 is etched to form the gate electrode 190. To describe this in detail, first, referring to FIG. 14, a photoresist pattern PR2 is formed on the metal layer 191 where the gate electrode 190 is to be formed. Then, referring to FIG. 15, the gate electrode 190 may be formed by etching the metal layer 191 using the photoresist pattern PR2 as a mask.

The above-detailed description is illustrative of the present disclosure. In addition, the above description shows and describes various embodiments of the present disclosure, and the present disclosure may be used in various environments in which the various embodiments are diversely combined or modified. That is, various changes or modifications to the embodiments are possible without departing from the scope of the concept of the disclosure herein, the scope equivalent to the disclosure, and/or the scope of skill or knowledge in the relevant art. The embodiments are provided to describe the various states for implementing the technical idea of the present disclosure, and various changes for specific applications and/or uses of the present disclosure are possible. Therefore, the detailed description of the present disclosure is not intended to limit the present disclosure to the disclosed embodiments.

What is claimed is:

1. A nitride-based semiconductor device comprising:
a substrate;
a channel layer on the substrate;
a bather layer on the channel layer;
a source electrode on the bather layer and spaced apart from the gate electrode;
a drain electrode on the bather layer and spaced apart from the gate electrode;
a gate electrode on the bather layer;
an insulating film on the bather layer and having openings at positions corresponding to the source electrode, the drain electrode, and the gate electrode; and
a sidewall spacer between the gate electrode and a nearest sidewall of the insulating film.

2. The device of claim 1, wherein the sidewall spacer comprises an insulating material.

3. The device of claim 1, wherein the sidewall spacer comprises a same material as the insulating film.

4. The device of claim 1, wherein the sidewall spacer is formed after the insulating film is formed.

5. The device of claim 1, further comprising a cap layer comprising an undoped region between the bather layer and the insulating film.

6. A nitride-based semiconductor device comprising:
a substrate;
a channel layer on the substrate;
a bather layer on the channel layer;
a gate electrode on the bather layer;
an insulating film on the bather layer and having an opening at a position corresponding to the gate electrode; and
a sidewall spacer between the gate electrode and a nearest sidewall of the insulating film,
wherein the insulating film comprises a protrusion into the opening.

7. The device of claim 6, wherein the side wall is on the protrusion and on the nearest sidewall of the insulating film.

8. The device of claim 7, wherein the protrusion is positioned at or below a lowest end of the nearest sidewall of the insulating film and has a height smaller than that of the nearest sidewall of the insulating film.

9. The device of claim 6, wherein the side wall comprises an insulating material and comprises a plurality of layers.

10. The device of claim 6, further comprising a cap layer comprising an undoped region between the bather layer and the insulating film.

11. A nitride-based semiconductor device comprising
a substrate;
a channel layer on the substrate;
a bather layer on the channel layer;
a gate electrode on the bather layer;
a first insulating film on the bather layer and having an opening at a position corresponding to the gate electrode;
a second insulating film on the first insulating film; and
the gate electrode on the second insulating film.

12. The device of claim 11, wherein the second insulating film is on the first insulating film and along a nearest sidewall of the insulating film in the opening.

13. The device of claim 11, wherein the gate electrode is not in direct contact with the first insulating film.

14. The device of claim 11, further comprising a buffer layer between the substrate and the channel layer.

15. The device of claim 11, wherein the second insulating film comprises:
a bottom surface in contact with the gate electrode; and
a sidewall spacer in contact with the second insulating film and on the gate electrode and the nearest sidewall of the insulating film.

16. A method of manufacturing a nitride-based semiconductor device, the method comprising:
forming a channel layer on a substrate, the channel layer comprising a GaN semiconductor;
forming a bather layer on the channel layer, the bather layer comprising an AlGaN semiconductor;
forming a source electrode and a drain electrode on the bather layer;
forming an insulating film having an opening on the bather layer, the insulating film having a sidewall in the opening;
forming a sidewall spacer on the sidewall of the insulating film; and
forming a gate electrode on the sidewall spacer.

17. The method of claim 16, wherein the sidewall spacer comprises an insulating material.

18. The method of claim 16, wherein forming the sidewall spacer comprises:
forming a patterned photoresist film on the insulating layer, the patterned photoresist film exposing the insulating layer at a position for a gate electrode;
forming the opening in the insulating film by etching the insulating layer, using the patterned photoresist film as a mask;
forming a second insulating film on the insulating film and in the opening; and
etching the second insulating film.

19. The method of claim 18, wherein forming the gate electrode comprises:
forming a metal layer on the insulating film and the sidewall spacer; and
forming the gate electrode by etching the metal layer.
